(19) United States
(12) Patent Application Publication
(10) Pub. No.: US 2005/0263813 A1
(43) Pub. Date: Dec. 1, 2005

(54) CAPACITOR ON THE SEMICONDUCTOR WAFER

(76) Inventor: Ching-Huei Tsai, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/709,846

(22) Filed: Jun. 1, 2004

(51) Int. Cl. H01L 27/108

(52) U.S. Cl. 257/303

(57) ABSTRACT

A capacitor disposed on a silicon substrate is disclosed. The silicon substrate has a first region, a second region, and a third region, which is adjacent to the first region and the second region, defined on its surface. The capacitor has a bottom electrode disposed in the first region and the third region on the surface of the silicon substrate, a dielectric layer disposed on the bottom electrode and the substrate, and a top electrode disposed in the second region and the third region on the surface of the dielectric layer.

### BACKGROUND OF INVENTION

1. Field of the Invention

The present invention relates to a capacitor, and more particularly, to a capacitor on a semiconductor wafer.

2. Description of the Prior Art

In semiconductor processing, a capacitor on a semiconductor wafer is designed with a lower conductive layer, an upper conductive layer and an intervening isolation layer. The two conductive layers are electrically isolated by the isolation layer at a predetermined distance and function as a bottom electrode and a top electrode, respectively. When a voltage is applied to the two electrode plates, charges are stored between them.

Please refer to FIG. 1, which is a schematic diagram of a capacitor 10 on a semiconductor wafer according to the prior art. As shown in FIG. 1, the semiconductor wafer comprises a silicon substrate 12 and a field oxide layer 14 on the surface of the silicon substrate 12. The capacitor 10 is disposed on the filed oxide layer 14 and has a bottom electrode 16, an isolation layer 18, and a top electrode 22 stacked in sequence. The semiconductor wafer further comprises a dielectric layer 26, first spacers 24, and second spacers 25 for isolating the capacitor 10 from other devices in the semiconductor wafer. In addition, at least one first contact plug 28 and second contact plug 32 are disposed on the bottom electrode 16 and the top electrode 22, respectively, for electrically connecting the capacitor 10 to other devices.

Please refer to FIG. 2, which is a top view of the capacitor 10. It is noted that only the bottom electrode 16, the top electrode 22, the first contact plugs 28, and the second contact plugs 32 are shown for clarity. It is obvious that the dimension of the bottom electrode L1 must be larger than the dimension of the top electrode L2 or there is not enough room to form the first contact plugs 28. In other words, when a capacitor is designed, the bottom electrode 16 must be larger than the top electrode 22 so that the contact plug 28 can be formed to electrically connect the bottom electrode 16 with external devices.

Typically, the bottom electrode 16 and the top electrode 22 are formed of a polysilicon layer or a doped polysilicon layer, which is the same as a gate of a transistor in a semiconductor wafer. As a result, the electrodes of the capacitor are normally formed with the gates of transistors simultaneously in the semiconductor wafer due to the requirement of process integration. To describe more precisely, one of the electrodes and the gate are formed of the same polysilicon layer at the same time.

Please refer to FIG. 3 and FIG. 4, which are two typical methods of fabricating the capacitor 10 and a gate 30 at the same time. The former one, which is shown in FIG. 3, forms the bottom electrode 16 and the gate 30 with the same polysilicon layer while the latter one, which is shown in FIG. 4, forms the top electrode 22 and the gate 30 with the same polysilicon layer. In the former one, the isolation layer 18 is formed individually so that a thickness of the isolation layer 18 can be adjusted. In the latter one, the isolation layer 18 is also used as a gate insulating layer for the transistor so that one process can be omitted.

Since both methods have theirs own advantages, both methods are widely used thereby. Since a semiconductor wafer is often designed by one company and then fabricated by another company, the process sequence may be changed if the wafer designer and the wafer fabricator are based on different methods. For example, one may design the capacitor according to the former method, in which a bottom electrode 16 with a dimension L1 is formed with the gate 30 together, but the fabrication of the capacitor may be performed according to the latter method, in which the electrode formed together with the gate is the top electrode. It may lead to a result of FIG. 5, in which the layout of the top electrode and that of the bottom electrode are exchanged in comparison with the FIG. 1. In other words, the top electrode 62 will have a dimension L1, which is larger than a dimension of the bottom electrode 54. As aforementioned, if the top electrode is larger than the bottom electrode, the contact plug of the bottom electrode cannot be made. In other words, the layout pattern of the capacitor must be re-designed, leading to an additional cost increase. Thus, a new capacitor structure is strongly needed to solve the aforementioned problem.

### SUMMARY OF INVENTION

It is therefore a primary objective of the present invention to provide a capacitor on a semiconductor wafer with flexible dimensions of both electrodes to solve the aforementioned problem.

In a preferred embodiment, the present invention provides a capacitor on a semiconductor wafer. The semiconductor wafer has a silicon substrate with a first region, a second region, and a third region, which is adjacent to the first region and the second region, defined on the surface of the silicon substrate. The capacitor has a bottom electrode disposed in the first region and the third region on the surface of the silicon substrate, a dielectric layer disposed on the bottom electrode and the substrate, and a top electrode disposed in the second region and the third region on the surface of the dielectric layer.

It is an advantage of the present invention that the capacitor comprises two electrodes partially overlapping each other. Thus, the problems caused by the process sequence change can be solved.

This and other objective of the present invention will no doubt become obvious to those of ordinary skill in the art after having read the following detailed description of the preferred embodiment which is illustrated in the various figures and drawings.

### BRIEF DESCRIPTION OF DRAWINGS

FIG. 1 is a sectional schematic diagram of a capacitor on a semiconductor wafer according to the prior art.

FIG. 2 is a top view of the capacitor in FIG. 1.

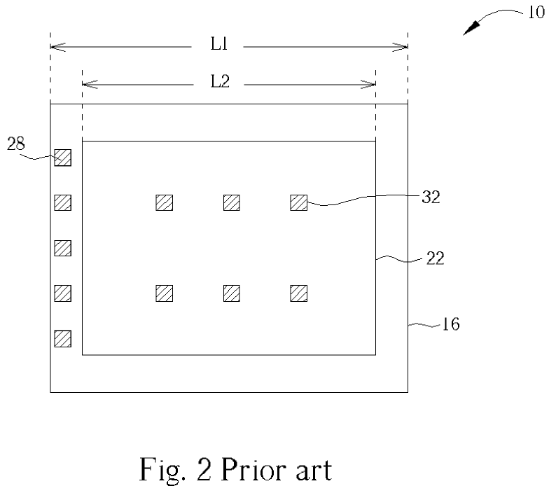

FIG. 3 is a schematic diagram of a fabricating method of a capacitor and a gate of a transistor.

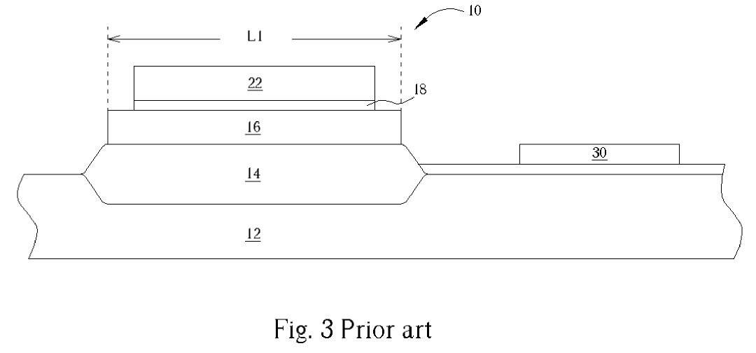

FIG. 4 is a schematic diagram of another fabricating method of a capacitor and a gate of a transistor.

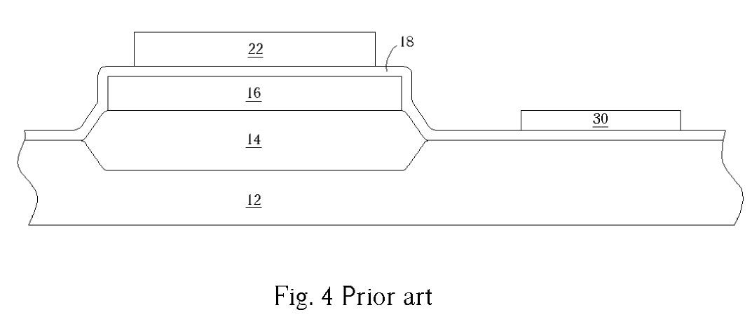

FIG. 5 is a sectional schematic diagram of a capacitor on a semiconductor wafer according to the prior art.

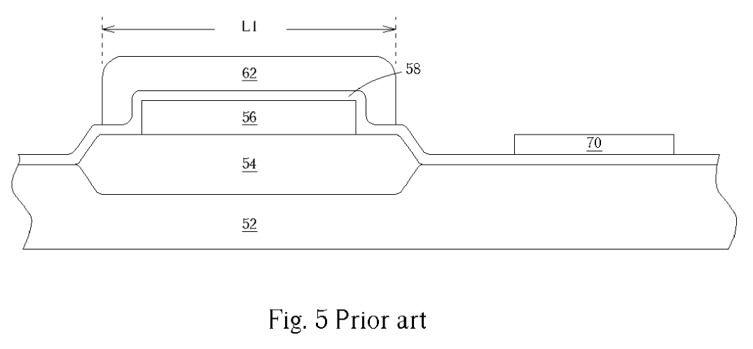

FIG. 6 is a sectional schematic diagram of a capacitor on a semiconductor wafer according to a first embodiment of the present invention.

FIG. 7 is a top view of the capacitor in FIG. 6.

FIG. 8 is a top view of the capacitor according to a second embodiment of the present invention.

FIG. 9 is a top view of the capacitor according to a third embodiment of the present invention.

FIG. 10 is a top view of the capacitor according to a fourth embodiment of the present invention.

### DETAILED DESCRIPTION

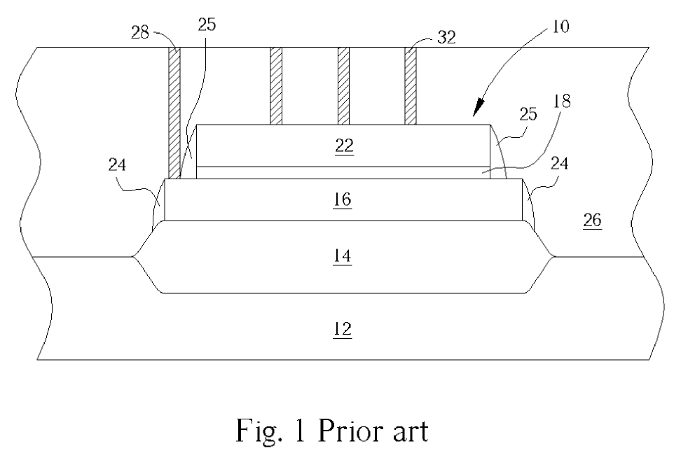

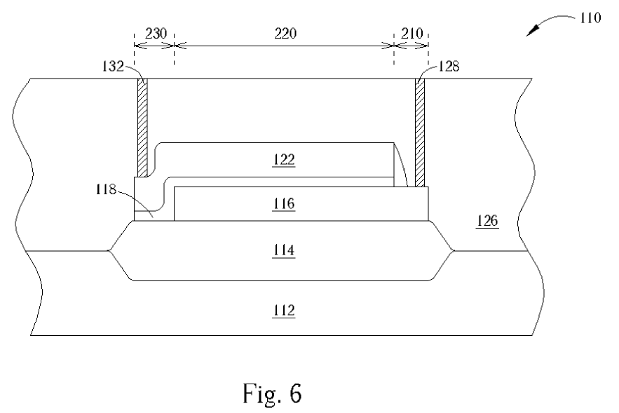

Please refer to FIG. 6, which is a schematic diagram of a semiconductor wafer 110 according to a first embodiment of the present invention. As shown in FIG. 1, the semiconductor wafer 110 has a silicon substrate 112, and a capacitor positioned on the surface of the silicon substrate 112. The silicon substrate 112 has a first region 210, a second region 230, and a third region 220 adjacent to the first region 210 and the second region 230. The capacitor comprises a first electrode 116, a first isolation layer 118, and a second electrode 122 stacked in sequence. The first electrode 116 is disposed in the first region 210 and the third region 220 on the surface of the silicon substrate 112. The first isolation layer 118 covers the first electrode 116 and the silicon substrate 112. The second electrode 122 is disposed in the second region 230 and the third region 220 on the surface of the isolation layer 118.

In a preferred embodiment of the present invention, the semiconductor wafer 110 further comprises a field oxide layer 114 located between the capacitor and the silicon substrate 112. The first electrode 116 and the second electrode 122 are both formed of a polysilicon layer or a doped silicon layer. The first isolation layer 118 is formed of a silicon oxide layer or a silicon nitride layer. In addition, the semiconductor wafer 110 further comprises a second isolation layer 126 covering the capacitor, a first contact plug 128 in the first region 210 and electrically connected with the first electrode 116 and a second contact plug 132 located in the second region 230 or the third region 220 and electrically connected to the second electrode 122.

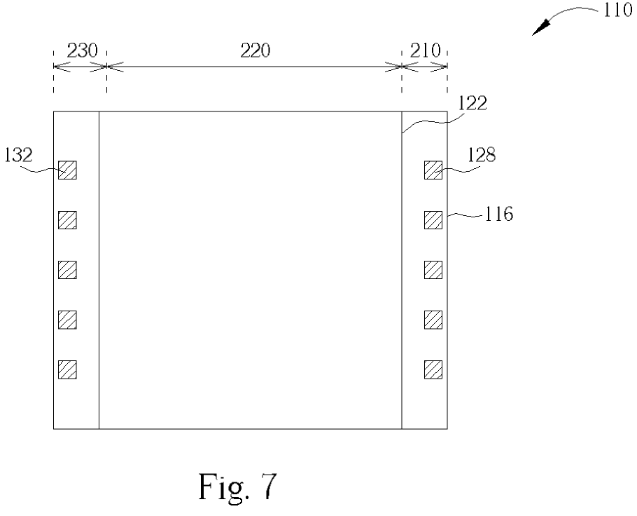

Please refer to FIG. 7, which is a top view of the capacitor shown in FIG. 6. As aforementioned, only the first electrode 116, the second electrode 122, the first contact plugs 128, and the second contact plugs 132 are shown for clarity. As shown in FIG. 7, the first electrode 116 and the second electrode 128 overlap each other partially so that a certain room will remain for forming the contact plug regardless of the process sequence change.

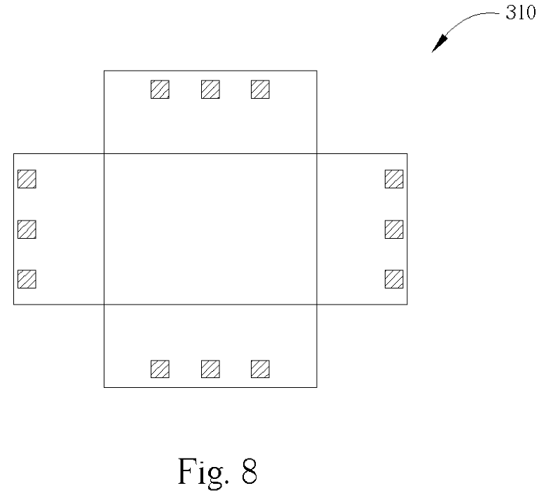

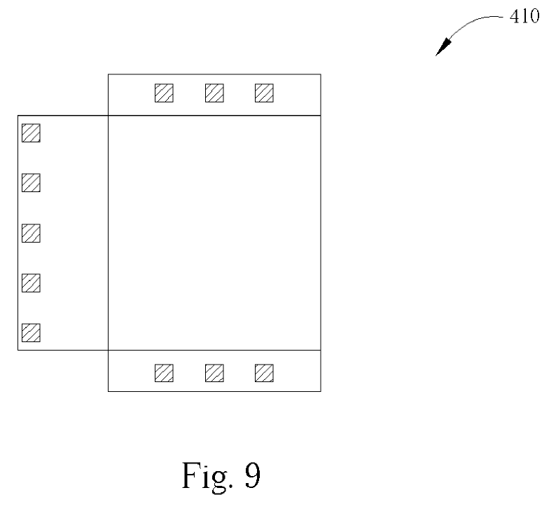

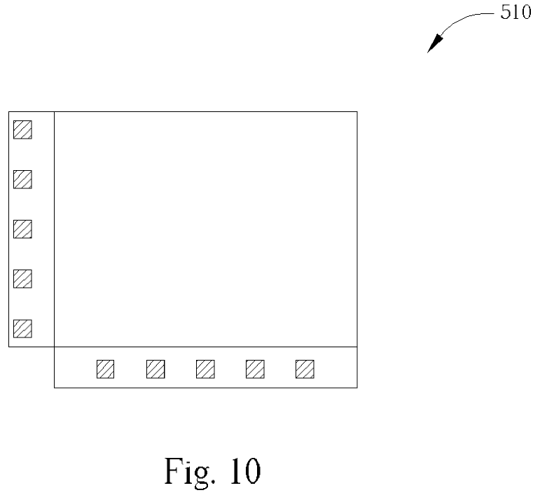

It is noted that the capacitor of the present invention is not limited to the layout pattern shown in FIG. 7, but can be realized by kinds of layout patterns according to the spirit of the present invention. Please refer to FIG. 8 to FIG. 10, which are top views of capacitors according to some typical embodiments of the present invention.

In comparison with the prior art, the top electrode of the capacitor in the present invention does not fully overlap the bottom electrode. Thus, even if the process sequence change is required, the contact plugs for the bottom electrode can still be formed without doing additional layout pattern modification. As a result, the fabrication cost and the fabricating time can be reduced thereby.

Those skilled in the art will readily observe that numerous modifications and alterations of the device may be made while retaining the teaching of the invention. Accordingly, the above disclosure should be construed as limited only by the metes and bounds of the appended claims.

1. A semiconductor wafer comprising:
a silicon substrate with a first region, a second region, and a third region defined on a surface of the substrate, the third region being adjacent to the first region and the second region; and
a capacitor disposed on the substrate, the capacitor comprising:
a first electrode disposed in the first region and the third region on the surface of the silicon substrate;
a first isolation layer covering the first electrode and the silicon substrate; and
a second electrode disposed in the second region and the third region on the surface of the isolation layer.

2. The semiconductor wafer of claim 1 wherein the capacitor further comprises a second isolation layer covering the capacitor and the silicon substrate.

3. The semiconductor wafer of claim 2 wherein the capacitor further comprises a first contact plug located in the second isolation layer and electrically connected to the first electrode.

4. The semiconductor wafer of claim 3 wherein the first contact plug is located in the first region.

5. The semiconductor wafer of claim 2 wherein the capacitor further comprises a second contact plug located in the second isolation layer and electrically connected to the second electrode.

6. The semiconductor wafer of claim 5 wherein the second contact plug is located in the second region or the third region.

7. The semiconductor wafer of claim 1 wherein the semi-conductor wafer further comprises a field oxide layer located beneath the first electrode.

8. The semiconductor wafer of claim 1 wherein the first electrode comprises a polysilicon layer or a doped polysilicon layer.

9. The semiconductor wafer of claim 1 wherein the second electrode comprises a polysilicon layer or a doped polysilicon layer.

10. The semiconductor wafer of claim 1 wherein the first isolation layer comprises a silicon oxide layer or a silicon nitride layer.

11. A capacitor disposed on a silicon substrate, the silicon substrate with a first region, a second region, and a third region defined on a surface of the silicon substrate, the third region being adjacent to the first region and the second region, the capacitor comprising:
a first polysilicon layer disposed in the first region and the third region on the surface of the silicon substrate;
a dielectric layer covering the first polysilicon layer and the silicon substrate; and
a second polysilicon layer disposed in the second region and the third region on the surface of the dielectric layer.

12. The capacitor of claim 11 wherein the capacitor further comprises a first contact plug electrically connected to the first polysilicon layer.

13. The capacitor of claim 12 wherein the first contact plug is located in the first region.

14. The capacitor of claim 11 wherein the capacitor further comprises a second contact plug electrically connected to the second polysilicon layer.

15. The capacitor of claim 14 wherein the second contact plug is located in the second region or the third region.

16. The capacitor of claim 11 wherein the capacitor further comprises a field oxide layer located under the first polysilicon layer.
